(19) United States
(12) Patent Application Publication
(10) Pub. No.: US 2025/0327884 A1
(43) Pub. Date: Oct. 23, 2025

(54) HYBRID AC/DC MAGNETOMETER WITH ATTITUDE DETERMINATION AND CONTROL SYSTEM

(71) Applicant: The Regents Of The University Of Michigan, Ann Arbor, MI (US)

(72) Inventors: Lauro V. OJEDA, Ann Arbor, MI (US); James CUTLER, Ann Arbor, MI (US); Mark B. MOLDWIN, Ann Arbor, MI (US)

(21) Appl. No.: 19/171,923

(22) Filed: Apr. 7, 2025

Related U.S. Application Data
(60) Provisional application No. 63/635,058, filed on Apr. 17, 2024.

(51) Int. Cl. G01R 33/02; B64G 1/24; B64G 1/36; G01R 33/00

(52) U.S. Cl. CPC G01R 33/0206; B64G 1/245; B64G 1/366; G01R 33/0029

(57) ABSTRACT

A hybrid magnetometer and attitude determination and control system (hybrid magnetometer attitude determination and control system). Many scientific and commercial satellites in low-Earth orbit (LEO) use attitude determination and control systems that enable control and knowledge of the spacecraft's attitude (the orientation the spacecraft). The hybrid magnetometer and attitude determination and control system is a single package that can be integrated into small satellites, such as CubeSats, and consists of a three-axis search coil AC magnetometer and three-axis quad-mag DC magnetometer. The search coil sensors also act as torque rods for part of the orbit. Noise cancellation algorithms enable scientific grade magnetic measurements from the system without needing a sensor boom.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

### 1.1 Scientific Rationale

Resource constrained magnetometers will be part of the experiment package of many of the future Heliophysics and LWS constellation missions because of the importance of measuring the magnetic field to meet a wide range of science objectives. The present disclosure is directed to measuring the small-scale structure of auroral current systems and the requirements for low-resource, low-cost, low-noise, high-cadence and easily manufactured magnetometer sensors.

The year 1977 brought the launch of the first co-orbiting satellites ISEE 1 and 2 and the ability to measure motions and derive scale lengths. The velocity and thickness of the bow shock were measured for the first time. The acceleration of plasma due to reconnection at the magnetopause was revealed proving the efficacy and reality of this long-proposed mechanism. The wave modes responsible for many upstream waves were identified. Some phenomena could not be probed adequately even with two spacecraft. The flux transfer event is associated with a moving magnetic tube. Mirror mode waves in the sheath also have a very localized structure.

Following the highly successful ISEE mission, the next step was to resolve spatial gradients, since a pair of spacecraft can only resolve one component of a gradient, along the spacecraft separation vector. To address this problem ESA with some assistance from NASA developed the four spacecraft Cluster mission that has now been operating for over 20 years. However, the separation of these spacecraft is too large to address the major issues raised by the ISEE 1 and 2 spacecraft. Thus, NASA's Magnetosphere Multiscale Mission (MMS) now operates at much smaller separations, down to 10 km. Both Cluster and MMS use an approximately tetrahedral configuration, which allows one to directly calculate the curl of the magnetic field, that is, the current density. This is an essential measurement in understanding the electrodynamics of different parts of the magnetosphere. Currents are the means by which stresses are communicated from one part of the magnetosphere to another, and also to the ionosphere, where the closure currents can induce significant perturbations on the ground.

Small-scale field-aligned currents and ion cyclotron waves: Understanding field-aligned currents (FAC) and the ionospheric closure currents is a fundamental problem of space physics since field-aligned currents provides information about MI mapping and coupling processes, energy flow and deposition, and contributes to significant ionospheric and ground-based space weather impacts. Traditionally large scale field-aligned currents have been mapped statistically from low-Earth orbiting spacecraft and the currently operating AMPERE project provides global maps of field-aligned currents by using the fleet of 66 Iridium satellites. These large-scale studies average out much of the structure that is observed, especially in the auroral zone and cusp. Even with high time resolution single spacecraft measurements, the field-aligned currents signatures can be smeared out by their relative motion. Studies that used high-cadence (50 Hz) magnetometer data found significant power at fine-scales and observations of ion cyclotron waves associated with precipitating electrons enabled the understanding of energy deposition at fine-scales. The hybrid magnetometer attitude determination and control system would enable probing of the DC and small-scale magnetic fluctuations associated with fine-scale field-aligned currents and ion cyclotron waves associated with precipitating ion and electron beams similar to what was done on FAST. The Quad-Mag sampling cadence can be set to 65 Hz or higher to overlap the low-frequency search-coil instrument to characterize large-amplitude field-aligned currents at the smallest scales.

A next step in probing the small-scale structure of field-aligned currents would be to fly a small constellation of micro-satellites in low-Earth polar orbit to measure the location, amplitude, motion and scale size of small-scale field-aligned currents. A proposed mission concept would have four spacecraft flying with two pairs of spacecraft, each pair flying in a pearls-on-a-string orbit, but the two orbital planes separated in the cross track direction (a combination of the ST5 and Swarm orbits).

### 1.2 Measurement Requirements

Large field-aligned currents can be measured even with extremely low-quality magnetometers such as those used in cell phones. The major field-aligned current systems were discovered and are even currently being analyzed with magnetometers with relatively poor resolution. Prior developments used measurements from the Triad spacecraft with a resolution of 12 nT and a cadence of 2.25 samples per second. Other developments included the AMPERE project that uses the Iridium satellites' navigation magnetometers, that have a resolution of 48 nT, and an effective cadence (after being down-sampled) of one sample every 200 s as well as higher cadence observations at 20 s with 2 s data available for storm times. The small satellites that made up the Space Technology 5 mission, flew fluxgate magnetometers provided 16 Hz vector magnetic measurement at 1.25 and 0.30 nT resolution in high (±64,000 nT) and low (±16,000 nT) ranges—though the effective resolution due to spacecraft noise was a few nT.

TABLE 1
Hybrid Magnetometer Science Traceability Matrix

| | | Mission and | | Processed | | |
|---|---|---|---|---|---|---|
| Science | Measurement | Measurement | Instrument | Data | Analysis | Science |
| Objective | Objective | Requirements | Requirement | Product | Product | Output |
| Determine | Quantify the | Simultaneous, | DC | Earths | DC and | Will know |
| mechanism | spatial scale | along and | magnetic | geomagnetic | ULF | the |
| that | of FAC and | cross-track | field (<1 nT | field | magnetic | conditions |
| create | the | separated | resolution | vector and | field | for small- |
| small- | relationship | measurements | @ 1 Hz | magnitude. | FAC | scale FAC |
| scale field- | between | of the DC | over full | FAC | maps | formation. |
| aligned | FAC and | magnetic field | Earth field | signatures, | | Will |
| currents | geomagnetic | and the AC | sampled at | location | | understand |
| (FAC). | conditions, | wave | 65 Hz) | spatial size. | | the role |
| | geophysical | environment | AC | ULF and | | of |
| | location and | at low to | magnetic | magnetic | | substorms |
| | ULF wave | auroral zone | field up to 2 | Wave | | on small- |
| | enviornment. | latitudes. | kHz. | power | | scale FAC |
| | | Polar orbital | | (down ro 10⁻¹ | | signatures. |
| | | coverage | | nT²/✓ | | |
| | | through all | | Hz) | | |
| | | local time | | DC and AC | | |
| | | sectors. | | Bus noise | | |
| | | | | ID (to better | | |
| | | | | than 1 nT) | | |

Table 1 shows the Traceability Matrix for a small-scale field-aligned currents mission. Though the hybrid magnetometer attitude determination and control system does not have the absolute field or noise floor capabilities of a mission such as Swarm, the technical objective of the present disclosure is to fully characterize and calibrate the instrument to determine the precision and noise floor of both the Quad-Mag and search-coil separately and in the integrated 1U package. This enables analysis of the sensors and the impact of their proximity unpowered and powered.

### 1.3 CubeSat State of the Art Magnetometers

In order to fly a magnetometer on a CubeSat for scientific uses (opposed to navigation), there have been several approaches taken. The first is to use miniature chip-based magnetometers such as Hall Probe chips, the gross magneto-resistive resistor (GMR) and anisotropic magneto-resistive (AMR) magnetometers. These devices are gaining some scientific flight heritage though suffer from noise, offset stability, linearity, radiation and temperature-gain sensitivity issues that are problematic for many space science missions. The other approach is to miniaturize fluxgate sensors to fit within the power, volume and mass constraints of a CubeSat. A number of efforts in this direction are ongoing. The SMILE (Small Magnetometer In Low-mass Experiment) has demonstrated extremely low noise (30 pT/√Hz at 1 Hz) in a comparatively small sensor housing (2×2×2 cm compared to the NASA ST5 sensor housing of 5×5×3 cm). This makes it possible to fly on a boom that fits within a CubeSat. Chip-based fluxgate magnetometers have also been developed, but their sensitivity is not yet comparable to space science-grade systems. In addition, Hybrid DC and AC magnetometers have been developed in an innovative single sensor design. This design though does not have flight heritage and would require a boom.

1.4 Justification of a New-Hybrid Magnetometer Integrated into an Attitude Determination and Control System

A new type of magnetometer is needed for small satellites and constellation class missions due to severe resource constraints of the spacecraft bus and the sheer number of instruments needed for a constellation mission. This requires low SWAP+C (low-size, weight and power+cost) WITH high-performance AND the ability to manufacture and test large numbers of instruments in a typical flight build schedule. These types of future missions also would require micro-satellite bus volumes and resources (power, telemetry, attitude control and knowledge) in order to address the outstanding questions of magnetospheric and heliospheric physics.

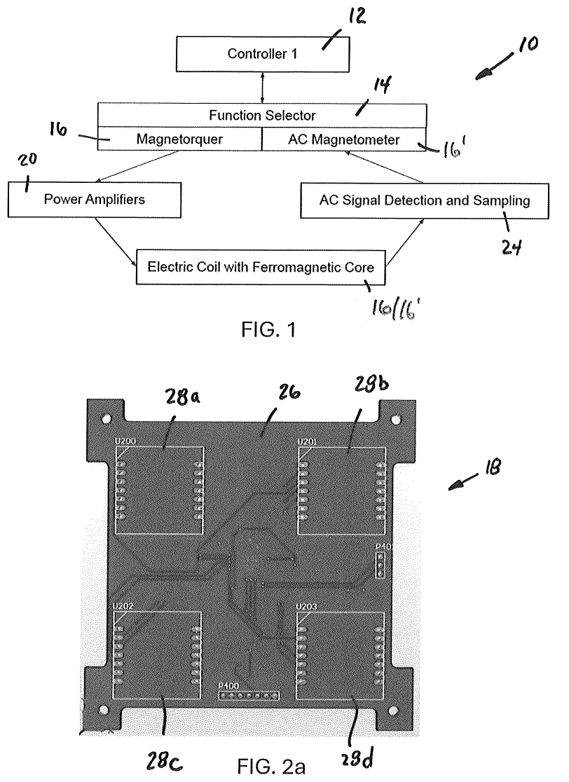

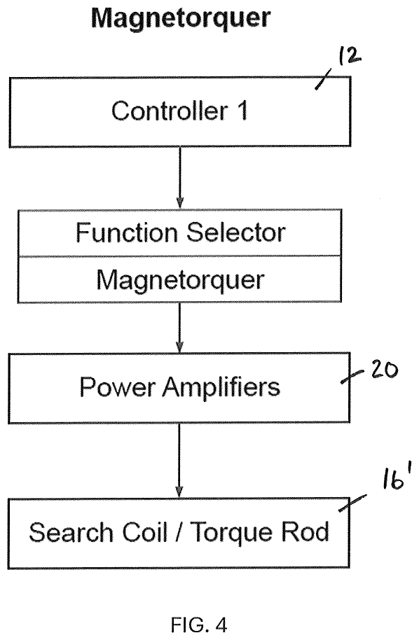

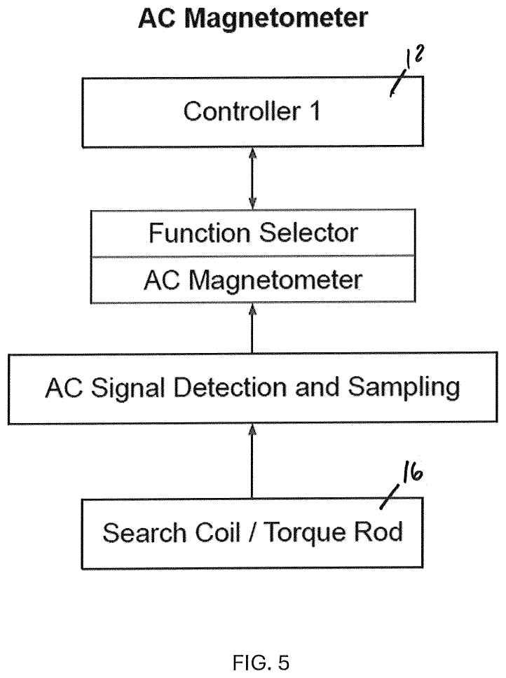

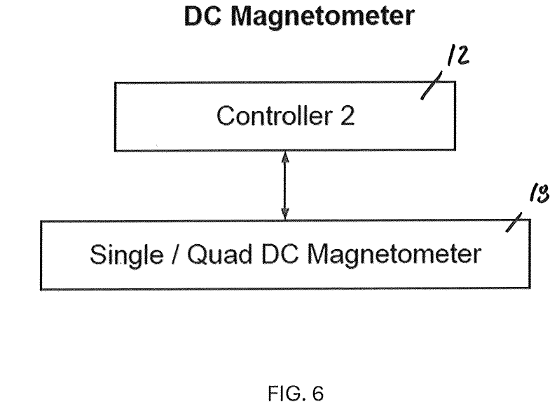

As shown in FIG. 1, the hybrid AC/DC magentometer with attitude determination and control system 10 will now be described. The system includes a controller 12 and a function selector 14 that selects between a magnetorquer function and an AC magnetometer function of the search coil 16. FIG. 4 illustrates a functional block of the search coil 16 as a magnetorquer 16′ as a first function and FIG. 5 illustrates a functional block of the search coil 16 as an AC magnetometer 16 according to a second function. FIG. 6 shows a function block diagram of a separate DC Quad magnetometer 18 which operates alongside the search coil 16 functioning as an AC magnetometer (FIG. 5) according to a second hybrid system. Using a Quad magnetometer 18 offers the advantage of noise cancellation in a boomless assembly. As shown in the operation of the system 10 in the first hybrid mode (FIG. 4), the magnetorquer function 16′ activates power amplifiers 20 to operate the electic coils 30a-30c in order to change the attitude of the satellite. In the AC magnetometer mode (FIG. 5), the electric coils 30a-30c provide a signal to an AC Signal Detection and Sampling module 24 that provides a signal to the controller 12 indicative to attitude of the satellite and/or the magnetic field strength at the satellite location.

As shown in the operation of the system 10 in the second hybrid mode (FIG. 5), the electic coils 30a-30c are operated as a magnetometer and provide a signal to an AC Signal Detection and Sampling module 24.

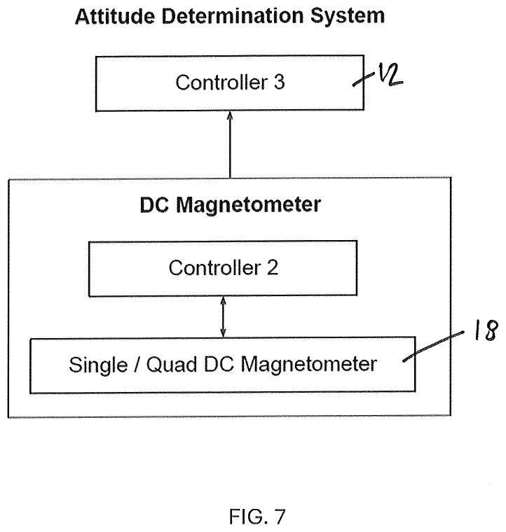

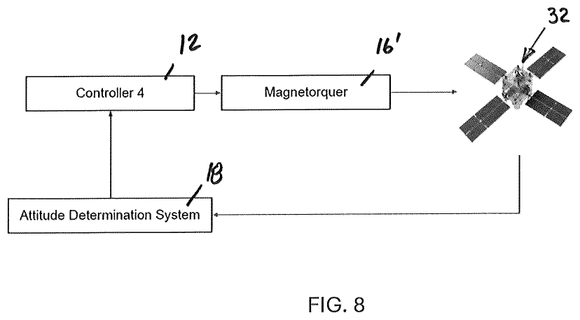

FIG. 7 shows a functional block diagram of the attitude determination system in which the Quad Mag 18 communicates with the controller 12 which then determines an attitude of the satellite. The controller 12 can include one or more controller modules implemented together or at separate locations to determine the attitude of the satellite 32. Thus the different controller modules that make up the controller 12 are labeled “controller 1”, “controller 2”, “controller 3” and “controller 4” although they can be implemented in one or more controller. FIG. 8 shows when the Hybrid System functions as a Magnetorquer 16′ to control the satellite's movement (attitude), the Controller 12 utilizes feedback from the attitude determination system that includes the DC Magnetometer 18 in Hybrid System 2 to close the control loop for changing the attitude of the satellite 32.

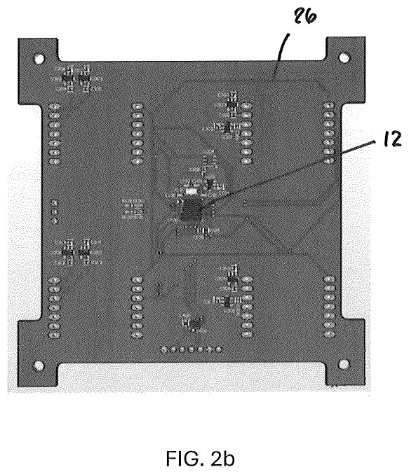

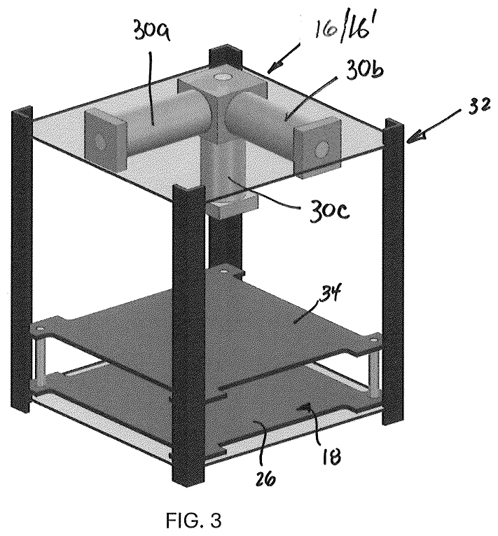

The AC Magnetometer 18 is shown in FIGS. 2a and 2b with FIG. 2a illustrating a top of a printed circuit board 26 with four magnetometers 28a-28d (quad magnetometers) mounted at cour corners of the printed circuit board 26. FIG. 2b illustrates the bottom of the printed circuit board 26 with controller electronics 12 mounted thereon. FIG. 3 illustrates a three-axis search coil ground electronics 30 fitting into a 1U Cube Satellite 32 formfactor (10×10×10 cm). The bottom electronics card 18 is the AC magnetometer 18 (QuadMag) while the top card 34 is the electronics for the system 10. The present disclosure encompasses several innovations to reduce size, weight and power and eliminate the need for a boom: (1) the Quad-mag 18 plus Machine Learning enables boomless DC magnetometry and (2) the hybrid search-coil magnetometer 16 with attitude determination torque rods enables a single 1U volume system to perform science measurements with the attitude determination and control system.

To address small-scale field-aligned currents problems, the DC magnetometer 18 and AC magnetometer 16 must provide sufficient samples per second in order to resolve time-varying and moving current systems and must be amenable to commercial manufacturing processes to enable scores of instruments to be built within typical mission timeframes and budgets. The present disclosure provides an integrated DC (magneto-inductive) and AC (search coil) magnetometer that has noise, sensitivity and sampling rate performance characteristics typical of modern digital fluxgate magnetometers in a package that is considerably smaller, requires less power, cheaper and that provides observations from DC to 2 KHz.

### 2.0 Magnetometer Description

The induction magnetometer that makes up the Quad-Mag 18 is based on the PNI Induction magnetometer electronics. PNI 3100 magnetometers have flight heritage on Cubesat Missions (e.g., the UM RAXs mission), but they were used primarily for attitude determination and control. The new “switch” electronics enabling the torque rods to cycle through attitude-determination mode to search-coil sense mode is the other major technology raising objectives.

### 2.1 The Proposed Instruments

Quad-Mag Hardware: The Quad-Mag board 18 includes four PNI RM3100 magneto-inductive magnetometers 28a-28d and a space-qualified micro-controller 12 (TI MSP430) on a single CubeSat form factor (10×10 cm) printed circuit board 26 that is herein referred to as the Quad-Mag 18. FIGS. 2A-2B shows the board 26 and Table 2 has some of its key figures of merit. By combining multiple sensors 28a-28d on a single board 26, the sensitivity is increased by a factor of two compared to a single instrument. In addition, the distributed sensors 28a-28d enable noise identification on small satellites providing science-grade magnetometer sensing that is key for both magnetic field measurements and attitude determination algorithm in low earth orbit. A single PNI RM3100 magnetometer itself has undergone full qualification testing and is part of the NASA Artemis Lunar Gateway Heliophysics Environmental and Radiation Measurement Experiment Suite (HERMES) Noisy Environment Magnetometer in a Small Integrated System (NEMISIS) magnetometer schedule for launch in early 2026.

TABLE 2
Key Figures of Merit of Quad-Mag

| Parameter | Value | |
|---|---|---|
| Dimensions | 10 × 10 × 3 | cm |
| Mass | 59.05 | g |
| Power consumption | 23 | mW |
| Dynamic range | +/−100 000 | nT |
| Sampling rate | 65 | Hz |
| Resolutions of 65 Hz | 5.34 | nT |
| Resolution of 1 Hz | 1.04 | nT |

| | |
|---|---|
| Noise Floor | 3.77 pT per ✓ (Hz) @ 1 Hz |

Search Coil and Torque Rod Hardware: The search coil electronics and the torque rod electronics have been developed independently. The search coil 16 was designed for ground-based measurements to observe ULF signals up to a few kHz that were generated by magnetic beacons for indoor localization purposes. The system was not tuned to minimize the noise floor and sensitivity, but was designed to use approximately the same sized cores that are employed in the hybrid magnetometer attitude determination and control system 10.

The torque rod system 16′ was designed for use on CubeSats 32. They essentially are electromagnets 30a-30c that are fired to align the spacecraft towards the Earth's magnetic field as part of the attitude determination and control system. For polar orbiting spacecraft the rods 30a-30c are “fired” usually for a few minutes near the magnetic poles where the field is strongest and nearly vertical. For the rest of the 90-minute orbit, the rods 30a-30c are not powered. The present disclosure switches over the torque rod electronics to the search coil electronics when not engaged in attitude control. One design feature of this project is to “deGauss” the rod by applying an AC current pulse after the “firing”. This, in itself, is innovative by enabling low magnetic moment torque rods 30a-30c for other missions that require low magnetic components and attitude determination and control systems. The remnant magnetic moment of the rods 30a-30c provide a DC offset to any DC magnetometer nearby.

Based on substantial experience in core material characterization, most recently by characterizing the magnetorquer rods 30a-30c built for the NASA CYGNSS satellites, the present disclosure provides a simple software model of non-ideal core solenoid inductance for improved understanding of coil parameters.

The main magnetic cleanliness requirement of the system is that the torque rods 30a-30c are not located so close to the Quad-Mag sensors 28a-28d that would saturate. Within a 1U volume the maximum distance apart is only about 5 cm, but the PNI3100 (28a-28d) has a dynamic range of +/−800,000 nT. Saturation and deGaussing experiments conducted on the PNI3100 (28a-28d) and though their off sets can change, the gain does not. For low earth orbit missions the on-orbit calibration of the sensors is straight-forward using reference magnetic fields. Since the science driven requirements are to observe variations in the field and not the absolute value of the field a hybrid magnetometer attitude determination and control system operation is possible.

### 2.2 The Proposed Algorithms and Software

Spacecraft Noise Identification Algorithm: Several past and current flight projects have taken advantage of new techniques to identify and remove noise from magnetometer systems that had insufficiently long booms to completely remove the noise through gradiometry. Recent work has proposed using multiple body mounted magnetometers with one on a short boom to identify noise spectrally. This is accomplished through machine learning algorithms that can spectrally isolate noise from the background field and magnetospheric and ionospheric signatures. The powerful Unsupervised Blind Source Separation (UBSS) algorithm can have more noise sources than magnetometers and is “blind” meaning it does not need to know the number, location, spectral content, or amplitude of the noise signals. However, UBSS relies on the assumption that each noise signal is spectrally sparse, and the method is computationally expensive.

A method named Wavelet Adaptive Interference Cancellation for Underdetermined Platforms (WAIC-UP) that is significantly (several orders of magnitude) less computationally expensive and automates the cleaning process so no user defined tuning parameters are needed. This enables low-power micro-controllers such as the MSP430 to do on-board spacecraft bus noise removal and the identification of space magnetic signatures due to temporally changing and flying through spatial structures. The present disclosure fully implements the algorithm in both lab experiments and simulation. The algorithm is used for both the Quad-Mag 18 and the search coil 16 data using the over-lap region of the Quadmag 18 and search coil 16 spectrum (up to 65 Hz). Spacecraft bus noise in the heart of the search coil frequency range (100-1 kHz) will not be sampled by the Quad-Mag 18 so other noise identification algorithms will be tested. Search coil noise identification is the main algorithm technology readiness level raising goal of this effort. Experiments can be performed in both simulation and in the laboratory with artificial noise sources to fully characterize not only the performance of the search coil 16 as a sensor, but also the different noise identification algorithms.

Switching and DeGaussing Control Software: The hybrid magnetometer attitude determination and control system 10 software consists of the “firmware” that samples all four magnetometers 28a-28d simultaneously to be used in the noise identification algorithm and the “switch” control software that fires the torque rods 30a-30c (in the magnetorquer mode) or samples the higher frequency magnetic signals from the rods 30a-30c (in the AC magnetometer mode). Our initial design includes sampling and recording the full wave form of the search coil data (3 axes, 16 bit per axes at 2 kHz=96 kps), but also will test using the MSP430 controller on the Quad-Mag 18 to spectrally process the search coil 16 wave form and return power as a function of frequency at a reduced (1 sec) cadence.

The control electronics 14 and software will “flutter” the current at the end of the torque rod 30a-30c firing to put a short pulse AC current on each of the rods 30a-30c to deGauss them.

### 3.0 Description of the New Hybrid Magnetometer Attitude Determination and Control System 10 Development

### 3.1 Integrated System

A three-layer design with the Quad-Mag 18 and Search Coil/Torque Rod 16/16′ electronics is stacked with a PC/104 connector and the three orthogonal torque rods 30a-30c at the top of the 1U chassis using the edges/corners as mechanical mounting locations (opposed to the fully encased sensors shown in FIG. 3). The systems is designed separately as EDU for full testing and characterization as magnetometers and then redesigned into a single hybrid magnetometer attitude determination and control system unit. The integrated system is tested going through “day-in-the-life” sequences of firing the torque rod and going into sense mode and testing the noise identification algorithms for the system itself. After this “self check” testing, laboratory noise tests are conducted by adding a variety of noise sources with a 3U and 6U mock CubeSat that have signals in both the DC and AC frequency range to fully be able to test the noise identification algorithms.

### 3.2 Relationship Between Data Products and Science Objectives

The main data products from the integrated hybrid magnetometer attitude determination and control system are from the three subsystems (Quad-Mag, Search Coil and Torque Rod). The performance of the three sub-systems will be determined independently to determine “best case” performance characteristics that will be used to compare with the performance of the integrated hybrid magnetometer attitude determination and control system. The Quad-Mag data includes the full three-axis magnetic field (each 24 bits) from each of the four sensors and the thermometer on the card (16 bits). The raw data are “counts” that are converted to nT after applying the calibrated gain factor. The thermal gain factor is then applied resulting in four magnetic vector time-series in units of [nT]. The signals are “mixed signals” consisting of the geophysical (or lab applied) field that are identical at all four sensors and noise signals from the other components and any other “lab” noise that have the same spectral characteristics but different amplitudes depending on the distance of the noise source from each of the sensors. The data are then processed using a UBSS machine learning technique to separate the geophysical signal from the noise. The single “cleaned” vector data is used to directly compare with the known applied “geophysical” signal to validate the requirements listed in the STM (Table 1). Statistics of the difference (e.g., RMSE and SNR) from the “cleaned” data and the applied known field will be the metrics of the quality of the instrument and technique.

The search coil data will be the full waveform (up to 2 kHz sampling rate from the three axes each at 16 bits) and will consist of the “mixed signal” of the geophysical (or lab applied) field (using signal generators to drive “noise” or “source” coils) and noise signals from the other components and other “lab” noise. The noise floor and frequency response of the search coil will be tested to characterize its performance. The main science requirement is to be able to measure ion cyclotron waves that typically are in the 10 s to 100 Hz range and therefore determining the noise floor in this frequency range will be the metric used to verify that we can meet the science requirements outlined in the STM. Unlike the Quad-Mag that has full-vector data from four independent sensors, the search coil's three axes will be treated as independent measurements and coupled with known location and orientations of noise sources will be used to extract the geophysical signal from the noise. The overlap region between the Quad-Mag 18 and Search Coil 16 is used to validate performance.

Finally, the torque rod 16′ data consists of the input current (power consumed), measured magnetic moment during firing, residual magnetic moment after firing, and the change in the magnetic moment after the deGauss AC currents have been applied. The requirements for this subsystem are not directly mapped in the STM but provide determination of how well the spacecraft orientation can be controlled. Depending on the configuration (center of mass, if 1U or 6U etc.) the torque needed will vary. Performance metric will be a relatively large magnetic moment that would provide significant torque to previously flown 3 U CubeSats. The Quad-Mag 18 provides the attitude determination that is directly related to the quality of the measured DC field.

### 4.1 Salient Features of the New Induction Magnetometer

### 4.1.1 Reduction in Size and Mass

The size and mass of the hybrid magnetometer attitude determination and control system 10 is modest compared to an attitude determination and control system and the equivalent DC and AC magnetometer sensors, electronics and booms. In addition, the Quad-Mag sensor 18 itself is under 60 g and fits on a CubeSat 32 form factor board 26 (see FIGS. 2a-2b and Table 2). Part of the design trades undertaken is the length to diameter ratio of the search coil/torque rods 30a-30c, the number of windings, and the gauge of wire. These all have an impact on the size of the field that can be created for a set amount of current and the sensitivity of the sensors for magnetic measurements. Four of the initial design requirements include fitting the entire system within a 1U volume, maximizing the distance between the torque rods and the Quad-mag, creating a field sufficient to align a “standard” 3U Cubesat in the ADS (about 0.25 A m2), and having DC magnetic field uncertainties of <1.5 nT at 1 Hz and search coil sensitivity sufficient to measure the fundamental frequency of proton cyclotron waves (down to about 10-1 nT2/root (Hz)).

### 4.1.2 Reduction in Power

Because of a major reduction in the number of components in the circuitry, the electronics board of a magneto-inductive instrument consumes much less power than that of a traditional magnetometer (order of 5 mW—less than a few hundred micro-amps at 3V). The total power consumption of Quad-Mag 18 is on the order of 25 mW including the MSP430 low-power processor 12. A typical commercial attitude determination and control system consumes approximately 300 mW average power, though much of that energy is consumed during the “firing” mode of actively controlling the attitude.

### 4.1.3 Enhancement of Noise Identification

The present disclosure improves the Quad-Mag 18 performance for noise identification and provides noise identification in the search coil magnetometer data. Since the primary science objectives are to measure ion cyclotron waves that are in the 10 to 100 Hz frequency range, there is significant overlap between the Quad-Mag 18 and search coil 16 aiding in the analysis and validation. A “typical” noise source on small spacecraft include reaction wheels that typically have spin rates in the 10-50 Hz range allowing testing of methods used with the Quad-Mag 18 to extend into the higher frequency domain of the search coil 16.

### 4.1.4 Temperature Tolerance

Like fluxgate magnetometers that have intrinsic temperature sensitivities (core material, changes in alignment and size of sensor assemblies, electronic components, the induction magnetometer 18 and search coil sensors 16 and circuit design also have temperature change effects. The impact for traditional fluxgates can be 1 to 2 nT/deg C. for offset and 0.01% per deg C. for gain. Hence many fluxgate designs have careful thermal design considerations as well as active heaters. Since the “packaging” of both the Quad-Mag 18 and the Search Coil 16 are internal to the spacecraft bus and not at the end of the boom, more passive heating options are available including the power dissipation of the ADS itself.

### 4.1.5 Low Cost

An object of the hybrid magnetometer attitude determination and control system 10 instrument is to reduce the cost of traditional spaceflight magnetometers by an order of magnitude (from 100 s of thousands of dollars to about a few 10 s of thousands of dollars—essentially the cost of a commercial attitude determination and control system, but with the added research quality DC and AC magnetic measurement capabilities). The use of standard PC/104 connectors and a 1U form factor will enable simple electronic and mechanical interfaces.

### 5.0 the Entry and Exit Technology Readiness Levels (TRL)

The hybrid magnetometer attitude determination and control system 10 technology development consists of integrating several separate already designed, built and characterized the Quad-Mag sensors 18 and the 3-axis search coil sensors 16 together. The new board's electronics enable the same rods 16 to be fired as torque rods 16′ and then switched over to search coil sense mode.

TABLE 3
(B.8-2) An Assessment of Technology Benefits and Advancements

| | |
|---|---|
| Primary Taxonomy Area (TA) | TX08: Sensors and |
| | Instruments |
| | TX08: 3 In Situ |
| | Instrument/Sensors |
| | TX08: 3/1 Field and Particle |
| | Sensors |
| Target Destination (The Sun, Earth, Moon, Mars, Others inside | Earth, Moon and Others inside |
| the Solar System, Outside the Solar System, Foundational | the Solar Syatem |
| Knowledge) | |

Start TRL: Quad-Mag (4) Search Coil Electronics (4) Torque Rods (9) Integrated System
including switching (between search coil and ACS operation) electronics (3)
Estimated End TRL (6) for integrated HyMag-ADCS system
Anticipated Benefits: Low-SWAP AC-DC science magnetometer in ACDS system for small
sattelites enable constellation mission concepts.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C #, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A satellite, comprising:
a satellite structure;
a hybrid magnetometer and attitude determination and control system mounted within the satellite structure and including a three-axis search coil AC magnetometer configured to act as torque rods
a three-axis DC magnetometer mounted to the satellite structure for determining an attitude of the satellite; and
a control system configured to receive satellite attitude determination signals from the three-axis DC magnetometer and to activate the three-axis search coil as torque rods to adjust an attitude of the satellite.

2. The satellite according to claim 1, wherein the DC magnetometer is a Quad mag DC magnetometer including four DC magnetometers mounted to a printed circuit board.

3. The satellite according to claim 1, wherein the satellite is a cube satellite.

4. The satellite according to claim 2, wherein the three-axis search coil AC magnetometer and the Quad mag DC magnetometer are each configured to detect a vector magnetic field strength at the satellite and the direction of the magnetic field to be used to determine the attitude of the satellite.

5. The satellite according to claim 4, wherein the control system provides noise cancellation of the magnetic field strength and attitude signals.

6. A satellite, comprising:
a satellite structure;
a hybrid magnetometer and attitude determination and control system mounted within the satellite structure and including a three-axis search coil AC magnetometer configured to act as torque rods; and
a control system configured to select between operating the three-axis search coil AC magnetometer as a magnetometer and as torque rods.

7. The satellite according to claim 6, further comprising a DC magnetometer mounted to the satellite structure for determining an attitude of the satellite.

8. The satellite according to claim 7, wherein the DC magnetometer is a Quad mag DC magnetometer including four DC magnetometers mounted to a printed circuit board.

9. The satellite according to claim 7, wherein the DC magnetometer provides attitude determination signals to the control system while the control system operates the three-axis search coil as torque rods to adjust an attitude of the satellite.

10. The satellite according to claim 6, wherein the satellite is a cube satellite.

11. The satellite according to claim 8, wherein the three-axis search coil AC magnetometer and the Quad mag DC magnetometer are each configured to detect a vector magnetic field strength at the satellite and the direction of the magnetic field to be used to determine the attitude of the satellite.

12. The satellite according to claim 11, wherein the control system provides noise cancellation of the magnetic field strength and attitude signals.
